(19) United States
(12) Patent Application Publication
(10) Pub. No.: US 2009/0001370 A1
(43) Pub. Date: Jan. 1, 2009

(54) Method and apparatus for extracting properties of interconnect wires and dielectrics undergoing planarization process

(76) Inventor: Wallace W. Lin, San Jose, CA (US)

Correspondence Address: WALLACE W. LIN, 1451 TURRIFF WAY, SAN JOSE, CA, 95132, US

(21) Appl. No.: 12/215,628

(22) Filed: Jun. 28, 2008

Related U.S. Application Data
(60) Provisional application No. 60/946,947, filed on Jun. 28, 2007.

(51) Int. Cl. H01L 23/58; G01R 31/12

(52) U.S. Cl. 257/48; 324/548; 257/E23.001

(57) ABSTRACT

The present invention provides a novel solution for simultaneously extracting the properties of the interconnect wires and the inter-wire dielectrics exposed to the IC planarization process.

### CROSS-REFERENCE TO RELATED APPLICATION

This application claims priority of a provisional application Ser. No. 60/946,947, filed on Jun. 28, 2007.

### FIELD OF THE INVENTION

The present invention relates to a method for simultaneously extracting the properties of the interconnect wires and the inter-wire dielectrics interacted with the planarization process during integrated-circuit manufacture.

### BACKGROUND OF THE INVENTION

Trends in the design and manufacture of microelectronic dies, or integrated circuits (ICs) are toward increasing miniaturization, circuit density, robustness, operating speeds and switching rates, while reducing power consumption and defects in the ICs. ICs are made up of a tremendous number (e.g., millions to hundreds of millions) of devices (e.g., transistors, diodes, capacitors, etc.), with each component being made up of a number of delicate structures, manufactured through a number of process steps. As IC manufacture technology continues to evolve and manufacturing of smaller sized components and more compact ICs become reality, the delicate structures likewise become smaller, more compact, and correspondingly, more delicate.

At 90- and 65-nanometer technology nodes, many (e.g., 10 or more) layers of conductor wires are required to interconnect the many smaller, more compact and more delicate structures in the ICs in accordance with the design specifications. (Note that these many layers of interconnect wires are insulated by a dielectric layer in between them. Such a dielectric layer is called an interconnect dielectric layer, an inter-wire dielectric layer, an inter-layer-dielectric layer, or an inter-wire-layer dielectric layer, hereafter. Also for simplicity, the interconnect wire is called the interconnect wire, hereafter.) Consequently, increasingly smaller, more compact and more delicate features of the interconnect wires are becoming essential to handle such formidable task in the design and manufacture of the ICs. However, the smaller, more compact and more delicate interconnect wire features are beginning to interact with the IC manufacturing processes, causing product yield loss. Such phenomena include the interaction between the interconnect wire features and the lithography process, the interaction between the interconnect wire features and the planarization process of the interconnect conductor and dielectric layers, etc. The interaction between the interconnect wire features and the planarization process of the interconnect conductor and dielectric layers such as, but not limited to, the chemical-mechanical polish (CMP) process, can cause non-uniformity of the conductor wire and dielectric thickness due to the dishing on the conductor wire surface and the erosion on the dielectric surface. Such effect reduces thickness of the interconnect conductor and dielectric layers, thus increasing the conductor wire resistance and the dielectric capacitance which can cause significant timing delays in circuits. Since there can be up to ten or more interconnect conductor and dielectric layers in the 65-nanometer technologies and beyond, the accumulated effect of the non-uniformity of the interconnect wire and dielectric thickness can be formidable after all interconnect conductor and dielectric layers receive the planarization process.

During semiconductor back-end manufacture process, every interconnect wire layer must be planarized before next layer of the interconnect dielectric is deposited. This planarization process is designed to prepare an even and smooth surface in order to facilitate accurate and reliable lithographic printing/patterning process for the layer of the interconnect wires that follow. Technologies involved in such planarization process in the semiconductor industry to date has not yet arrived at a good solution in containing the aforementioned manufacture yield problem caused by the interaction between the fine features of the interconnect wires and the planarization process. Such problem may aggravate further as the technology moves to 45 nm node and beyond. To improve the manufacturing and product yield, it is important to characterize the impact of the interconnect wire and dielectric planarization process on the interconnect related parameters and properties and the extent these parameters and properties are affected. Such results can feedback to the planarization process control and thus are essential for improving the planarization process.

The interconnect wire thickness, its dishing amount, and the inter-wire dielectric thickness and its erosion amount are the main parameters to monitor in characterizing the impact of the planarization process on the IC interconnect wire and dielectric properties. Commonly used methods for characterizing interconnect wire and dielectric thickness are physical and electrical methods. Physical methods include profilometry, Atomic Force Microscopy (AFM), Secondary Electron Microscopy (SEM), etc. Electrical methods include Current-Voltage (I-V) and Capacitance-Voltage (C-V) method. Physical characterization methods are generally accurate but time-consuming. Electrical characterization methods can be as accurate as the physical methods but extremely fast and can be automated to collect a large amount of data in a short time, thus more suitable for use in the IC fabrication plants. Nonetheless, the accuracy of the electrical methods in characterizing the effect of the planarization process on the interconnect wire and dielectric properties depends strongly on the design of the structures to be characterized. The characterization method and the structures to be characterized should work together to achieve accurate and reliable results. Moreover, the interconnect wire dishing and the inter-wire dielectric erosion have not yet been characterized directly and simultaneously by the electrical methods to date. This present invention provides a solution based on a method of simultaneously extracting the interconnect wire thickness, its dishing, and the inter-wire dielectric thickness and its erosion by using the electrical tests in conjunction with a set of test structures and proprietary extraction algorithms.

### SUMMARY OF THE INVENTION

The present invention for the first time presents an art of simultaneous extraction for the properties of the interconnect wires and the inter-wire dielectrics exposed to the IC planarization process. The art is achieved with a set of simple interconnect-wire structures by slightly varying (or perturbing), one at a time, one physical parameter in one structure while keeping the remaining physical parameters the same in remaining structures. Since the method is electrical based, it is extremely fast and reliable comparing with the physical measurements currently used for measuring the properties of the interconnect wires and the inter-wire dielectrics. The capability of handling a large amount of data in a short time scale makes this invented method particularly suitable for use in IC fabrication plants,

The method and apparatus presented in this invention, when used in collaboration with or embedded in other test structures that are well designed to cover a broad spectrum of interconnect wire layout features and scenarios, will provide an effective and efficient solution for characterizing and evaluating the impact of the IC planarization process on the interconnect wire and dielectric properties in circuit layouts on a full-chip level.

### BRIEF DESCRIPTION OF THE DRAWINGS

FIG. 1 is a cross sectional view of the interconnect conductor and dielectric layers of an IC layout after the planarization process, showing dishing in the conductor layer and erosion in the dielectric layer.

FIG. 2 is an illustration showing the test structures and measurement configuration for characterizing the interconnect wire thickness and its dishing amount after the planarization process.

FIG. 3 is an illustration showing the test structures and measurement configuration for characterizing the inter-wire dielectric thickness and its erosion amount after the planarization process.

### DETAILED DESCRIPTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

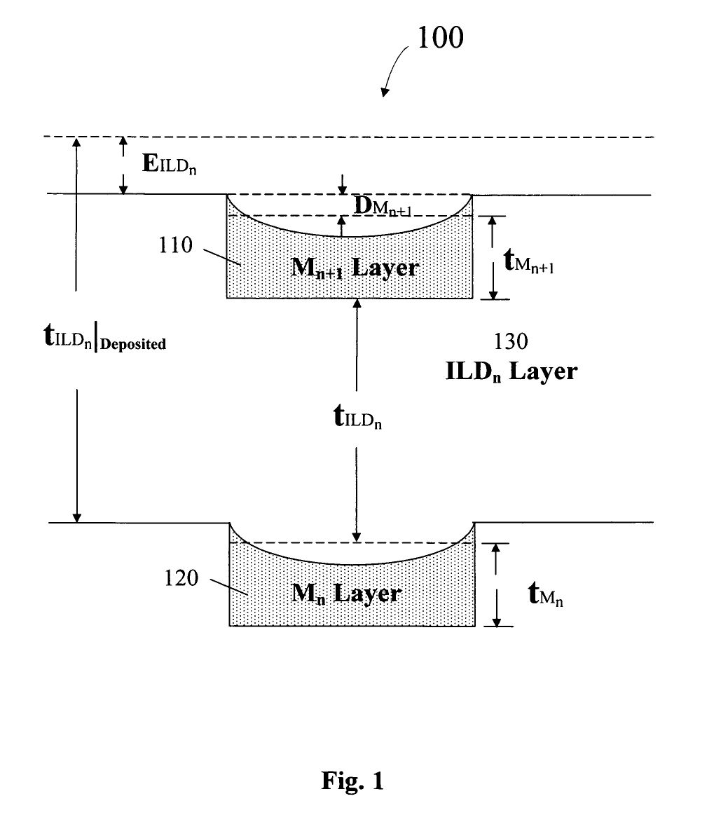

The Illustration 100 in FIG. 1 shows the cross sectional view of the interconnect wire layers of an IC layout after the planarization process. The concave shape of the metal wire is caused by the dishing effect from the planarization process. Given a total of n layers of the interconnect wires formed during an IC manufacture process, t_{M}_{ₙ} denotes the metal thickness of the n^{th} metal layer 120, an average value taking into account the concave portion, measured from the electrical I-V method. t_{ILD}_{ₙ} is the dielectric thickness of the n^{th} layer of the inter-wire or inter-layer dielectrics (abbreviated as ILD) 130 formed between the (n+1)^{th} metal layer 110 and the n^{th} metal layer 120, an average value taking into account the concave portion of the n^{th} layer of the metal, measured from the electrical C-V method.

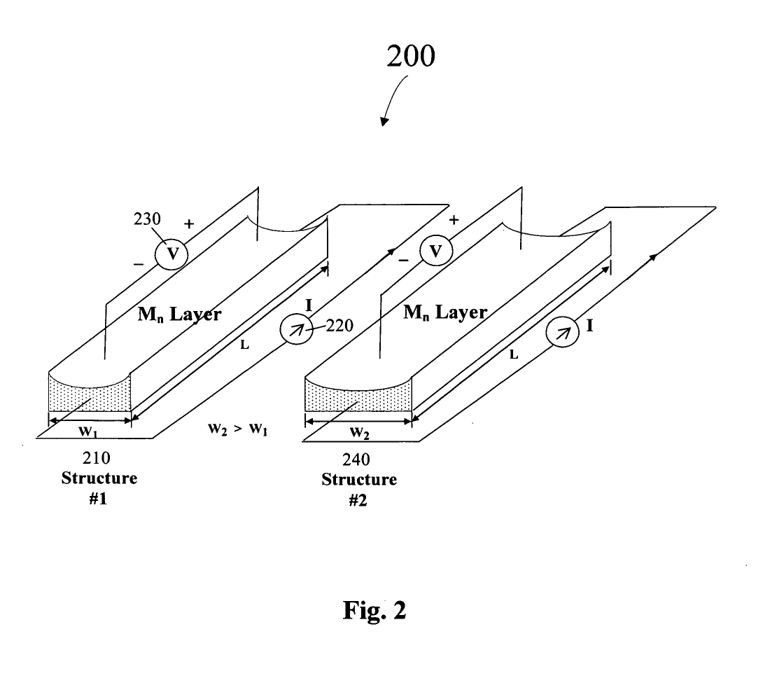

The thickness of the n^{th} layer of metal wire 220 is measured with the test structures shown in Illustration 200 in FIG. 2. Two test structures 210 and 240, with the former (w=w₁) narrower than the latter (w=w₂, w₂>w₁) and both having the same length L, are measured by a 4-point I-V method in which the current is forced to flow from one end of the wire to the other end with a current source 220. The voltage is measured between the two ends of the wire with a voltmeter 230. The I-V data of these two structures give rise to resistance R₁ and R₂, respectively, which can be expressed as a function of w₁, w₂, Δw and t_{M}_{ₙ}, as shown below. Δw is the bias (i.e., difference) between the drawn width and the actual width after the manufacture process.

$$\begin{matrix}\frac{{V}_{1}}{{I}_{1}} = {R}_{1} = ρ \frac{L}{( {w}_{1} + Δ w ) {t}_{{M}_{n}}} & ( 1 ) \\ \frac{{V}_{2}}{{I}_{2}} = {R}_{2} = ρ \frac{L}{( {w}_{2} + Δ w ) {t}_{{M}_{n}}} & ( 2 )\end{matrix}$$

Solving (1) and (2) gives Δw and t_{M}_{ₙ}:

$$\begin{matrix}Δ w = \frac{{R}_{2} {w}_{2} - {R}_{1} {w}_{1}}{{R}_{1} - {R}_{2}} & ( 3 ) \\ {t}_{{M}_{n}} = ρ \frac{L}{( {w}_{1} + Δ w ) {R}_{1}} & ( 4 )\end{matrix}$$

Note that the calculated t_{M}_{ₙ} here is an average thickness of the n^{th} layer metal wire because the measured I-V data automatically reflect the effect of the dished (concave) surface of the wire.

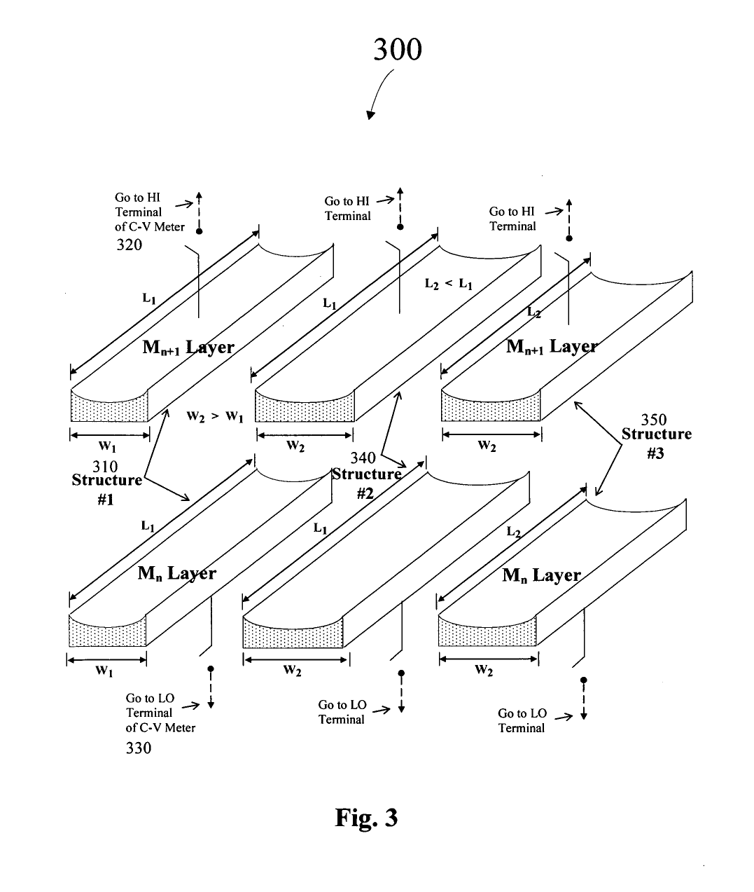

The illustration 300 in FIG. 3 shows the test structures for measuring the inter-wire dielectric thickness. There are three test structures, 310 (Structures #1), 340 (Structures #2) and 350 (Structures #3). One pair of the test structures, 310 and 340, has same length (L₁) but with different widths, with 310 (w=w₁) narrower than 340 (w=w₂, w₂>w). The other pair, 340 and 350, has same width (w₂) but with different length (L₁ and L₂, L₂<L₁). The three capacitance structures are formed between the (n+1)^{th} metal layer and the n^{th} metal layer. For each of the structures, the High (HI) terminal 320 of the C-V meter is connected to the (n+1)^{th} metal layer of the structure and the Low (LO) terminal 330 connected to the n^{th} metal layer.

There are three capacitance components in the total capacitance (Cᵢ) of each of the test structures: The area capacitance between the Mₙ₊₁ and Mₙ layer (C_{iA}), the sidewall fringing capacitance between the Mₙ₊₁ and Mₙ layer (C_{if}), and the sum of the miscellaneous capacitances (C_{iMisc}) including the pad-to pad capacitance (there are two probing pads connected to the HI and LO terminal of the C-V meter for each structure), the pad-to-connecting_wire capacitance, the pad-to-structure_wire capacitance, the connecting_wire-to-structure_wire capacitance, and the connecting_wire-to-connecting_wire capacitance, where i denotes the structure number. The two probing pads and the two connecting wires leading to the probing pads from the test structure generally do not overlap vertically and the capacitance between the two connecting wires is usually small. For the capacitance between the two probing pads, its value is not insignificant when the two pads are placed adjacently. If the two probing pads and the two connecting wires for each of the structures are arranged in a same manner in terms of their locations and the distance in between them, and the value of w₁ and w₂ as well as L₁ and L₂ in the structures do not differ much (i.e., close to each other), then Ci_{Misc} can be assumed to be same for all three structures here.

Thus, if w₁ is close to w₂ and L₁ close to L₂, the total capacitance of the three structures, can be expressed by (5), (6) and (7), respectively as:

$$\begin{matrix}{C}_{1} = {C}_{Misc} + {C}_{1 A} + {C}_{1 f} = {C}_{Misc} + \frac{{ɛ}_{ILD} ( {w}_{1} + Δ w ) {L}_{1}}{{t}_{{ILD}_{n}}} + {C}_{1 f} & ( 5 ) \\ {C}_{2} = {C}_{Misc} + {C}_{2 A} + {C}_{2 f} = {C}_{Misc} + \frac{{ɛ}_{ILD} ( {w}_{2} + Δ w ) {L}_{1}}{{t}_{{ILD}_{n}}} + {C}_{2 f} & ( 6 ) \\ {C}_{3} = {C}_{Misc} + {C}_{3 A} + {C}_{3 f} = {C}_{Misc} + \frac{{ɛ}_{ILD} ( {w}_{2} + Δ w ) {L}_{2}}{{t}_{{ILD}_{n}}} + \frac{{L}_{2}}{{L}_{1}} {C}_{2 f} & ( 7 ) \\ {C}_{1 f} = {C}_{2 f} = \frac{{πɛ}_{ILD} {L}_{1}}{2 ln ( \frac{{t}_{{ILD}_{n}}}{{t}_{{M}_{n + 1}} {\vert}_{SW}} )} & ( 8 )\end{matrix}$$

From (5) and (6), the average thickness of the n^{th} interconnect dielectric layer can be solved as

$${t}_{{ILD}_{n}} = \frac{{ɛ}_{ILD} ( {w}_{1} - {w}_{2} ) {L}_{1}}{( {C}_{1} - {C}_{2} )} \qquad ( 9 )$$

Feeding t_{ILD}_{ₙ} and Δw [from (3)] to (5), we have

$${C}_{2 f} = \frac{{C}_{3} - {C}_{2} - ( \frac{{L}_{2}}{{L}_{1}} - 1 ) \frac{{ɛ}_{ILD} ( {w}_{2} + Δ w ) {L}_{2}}{{t}_{{ILD}_{n}}}}{( \frac{{L}_{2}}{{L}_{1}} - 1 )} \qquad ( 10 )$$

Feeding C_{2f} to the formulation of the fringing capacitance in (8), the sidewall height of the (n+1)^{th} metal layer can be solved:

$${t}_{{M}_{n + 1}} {\vert}_{SW} = {t}_{{ILD}_{n}} exp ( \frac{- {πɛ}_{ILD} {L}_{1}}{2 {C}_{2 f}} ) \qquad ( 11 )$$

From (6), the miscellaneous capacitances can be solved:

$${C}_{Misc} = {C}_{2} - \frac{{ɛ}_{ILD} ( {w}_{2} + Δ w ) {L}_{2}}{{t}_{{ILD}_{n}}} - {C}_{2 f} \qquad ( 12 )$$

Based on Illustration 100 in FIG. 1, the average dishing amount of the wire is the difference between the metal sidewall height and the average metal thickness:

D_{M}_{ₙ₊₁}=t_{M}_{ₙ₊₁}|_{SW}−t_{M}_{ₙ₊₁} (13)

The average dielectric erosion is the difference between the thickness of the deposited n^{th} ILD layer and the sum of the Mₙ₊₁ thickness and the n^{th} ILD thickness between the Mₙ₊₁ and Mₙ layer, assuming the dishing in the Mₙ₊₁ and Mₙ layer is similar:

E_{ILD}_{ₙ}=t_{ILD}_{ₙ}|_{Deposited}−(t_{M}_{ₙ₊₁}+t_{ILD}_{ₙ}) (14)

Note that the first two set of structures (Structures #1 and #2) used in extracting the average inter-wire dielectric thickness and erosion properties can also be used for extracting the average interconnect wire thickness. Either the upper or the lower layer of the wires in the two structures can be used for this purpose. Therefore, the three structures shown in FIG. 3 are the minimum set of test structures that can be used to extract simultaneously the average thickness and dishing amount of the interconnect wire and the average thickness and erosion amount of the inter-wire dielectric. More structures of slightly varying wire widths with the wire length fixed and/or of slightly varying the wire length with the wire width fixed should further improve accuracy and reliability of this extraction method. In such cases, multiple-parameter fittings to the measured data of (C₁, C₂, . . . , C_{N}) as a function of C_{Misc}, C_{f} (or t_{M}_{_{n−1}}|_{SW}) and t_{ILD}_{ₙ} with the known variables of the w's, the L's and Δw can be performed.

Note that the above method and apparatus can provide a total solution for characterizing and evaluating the impact of the planarization process on the interconnect wire and dielectric properties in circuit layouts on a full-chip level if the method and apparatus are used in conjunction or collaboration with other test structures that are well designed to cover a broad spectrum of interconnect wire layout scenarios that can fully capture the interaction between the planarization process and the interconnect wire layout features.

The present invention may be practiced as a software invention, implemented in the form of a machine-readable medium having stored thereon at least one sequence of instructions that, when executed, causes a machine to effect the invention. More particularly, in addition to being physically embodied in physical IC circuit layouts, embodiments of the present invention may also be practice in virtual (but tangible) form where codes stored on a machine-readable medium contains a configuration of an IC circuit layout having the IC interconnect wire layout arrangement for extracting properties of the interconnect wires and dielectrics. Such should be interpreted as being within a scope of the present invention (i.e., claims). With respect to the term “machine”, such term should be construed broadly as encompassing all types of machines, e.g., a non-exhaustive listing including: computing machines, non-computing machines, communication machines, etc. Similarly, with respect to the term “machine-readable”, such term should be construed broadly as encompassing a broad spectrum of mediums, e.g., a non-exhaustive listing including: magnetic medium (floppy disks, hard disks, magnetic tapes, etc.), optical medium (CD-ROMs, DVD-ROMs, etc.), etc.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. An integrated-circuit interconnect wire layout arrangement, comprising:
three test structures, each formed by an upper and a lower interconnect wire layer of the same length and width, and with a dielectric layer between the two wire layers;
the first and the second structure having the same wire length and slightly different wire width; and
the second and the third structure having the same wire width and slightly different wire length.

2. The arrangement as claimed in claim 1, further comprising a machine-readable medium having stored thereon at least one sequence of instructions that, when executed, causes a machine to implement the arrangement.

3. A method of simultaneously extracting properties of the interconnect wires and dielectrics in integrated circuits, comprising:
forming the designed three structures physically via integrated-circuit manufacture process;
performing electric current-voltage measurements on either the upper or the lower wire layer of the first and second structure;
performing electric capacitance-voltage measurements on all three structures; and
performing analysis on the measured current-voltage and capacitance-voltage data to extract the thickness and dishing amount of the interconnect wire, and the thickness and erosion amount of the interconnect dielectric.

4. The method as claimed in claim 3, wherein the integrated-circuit manufacture process is a planarization process for interconnect wires and dielectrics.

5. The method as claimed in claim 4, wherein the planarization process is a chemical-mechanical polish (CMP) process.

6. The method as claimed in claim 3, wherein performing electric current-voltage measurements comprises:
forcing a current from one end to the other end of an interconnect wire layer with a current source and measuring a voltage between its two ends with a voltmeter; and
recording the measured current and voltage data.

7. The method as claimed in claim 3, wherein performing electric capacitance-voltage measurements comprises:
connecting a capacitance-voltage meter between the upper and lower interconnect wire layer of a test structure;
measuring capacitance and voltage data from a test structure; and
recording the measured capacitance and voltage data.

8. The method as claimed in claim 3, wherein the thickness and dishing amount of the interconnect wire and the thickness and erosion amount of the interconnect dielectric layer extracted in the analysis are average values, taking into account the concave surface of the wire after the manufacture process.

9. The method as claimed in claim 3, wherein performing analysis further comprises:
extracting the bias between the drawn width and the actual width of the interconnect wire layer after the manufacture process;
extracting the sidewall fringing capacitance and the sidewall height of the interconnect wire layer; and
extracting the miscellaneous capacitance of the test structures, a total of the capacitances including the pad-to pad capacitance, the pad-to-connecting_wire capacitance, the pad-to-structure_wire capacitance, the connecting_wire-to-structure_wire capacitance, and the connecting_wire-to-connecting_wire capacitance in the test structures.

10. The method as claimed in claim 3, further comprising a machine-readable medium having stored thereon at least one sequence of instructions that, when executed, causes a machine to implement the method.
